(19) United States
(12) Patent Application Publication
(10) Pub. No.: US 2015/0263704 A1
(43) Pub. Date: Sep. 17, 2015

(54) DATA DRIVING CIRCUIT

(71) Applicant: SK hynix Inc., Gyeonggi-do (KR)

(72) Inventor: Hyun-Bae LEE, Gyeonggi-do (KR)

(21) Appl. No.: 14/445,987

(22) Filed: Jul. 29, 2014

(30) Foreign Application Priority Data
Mar. 12, 2014 (KR) 10-2014-0028819

(51) Int. Cl. H03K 3/012

(52) U.S. Cl. CPC H03K 3/012

(57) ABSTRACT

A data driving circuit includes: an equalizer which transmits an input data as an output signal while a dock is at a first level and equalizes the output signal while the clock is at a second level; a driver which drives an output data in response to the input data; and a compensator which drives the output data in response to the output signal.

### CROSS-REFERENCE TO RELATED APPLICATIONS

The present application claims priority of Korean Patent Application No. 10-2014-0028819, filed on Mar. 12, 2014, which is incorporated herein by reference in its entirety.

### BACKGROUND

1. Field

Various embodiments of the present invention relate to a data driving circuit for driving a data.

2. Description of the Related Art

In a data driving circuit for driving data to a transmission line having a heavy load, simply controlling the driving power cannot compensate for the heavy loading. Thus, a pre-emphasis or a de-emphasis scheme of a Feed Forward Equalizer (FFE) may be applied to the data driving circuit. However, the FFE causes a great amount of current consumption and the FFE is vulnerable to random jitter and offset caused by noise.

### SUMMARY

Various embodiments of the present invention are directed to a data driving circuit that prevents failure of a data transmission due to data overdrive offset and random jitter,

In accordance with an embodiment of the present invention, a data driving circuit may include an equalizer suitable for transmitting an input data and an inverted input data as an output signal and an inverted output signal while a clock is at a first level, and equalizing the output signal while the clock is at a second level; a driver suitable for driving an output data and an inverted output data in response to the input data and the inverted output signal; and a compensator suitable for driving the output data and the inverted output data in response to the output signal and the inverted output signal.

The compensator may drive the output data and the inverted output data by inverting the output signal and the inverted output signal. The driving power of the compensator may be less than the driving power of the driver.

The equalizer may include a differential amplifier suitable for outputting the output signal to a first output terminal and the inverted output signal to a second output terminal by differentially amplifying the input data inputted through a first input terminal and the inverted input data inputted through a second input terminal, and a switch suitable for electrically coupling the first output terminal to the second output terminal while the clock is at a second level, and electrically decoupling the first output terminal from the second output terminal while the clock is at a first level.

In accordance with an embodiment of the present invention, a data driving circuit may include an amplifying unit suitable for outputting first and second amplified signals by differentially amplifying first and second input data for a predetermined duration in each period of a clock, a driving unit suitable for outputting first and second output data by differentially amplifying the first and second input data, and a compensation unit suitable for reducing a swing of the first and second output data using the first and second amplified signals.

The compensation unit may drive the first and second output data so that the first amplified signal may lower an absolute level of the second output data, and the second amplified signal may lower an absolute level of the first output data.

A driving power of the compensation unit may be less than a driving power of the driving unit. The amplifying unit may include first and second capacitors coupled to nodes of the first and second amplified signals, respectively.

The second input data may be an inverted version of the first input data, the second amplified signal may be an inverted version of the first amplified signal, and the second output data may be an inverted version of the first output data.

### BRIEF DESCRIPTION OF THE DRAWINGS

FIG. 1 is a block diagram illustrating a data driving circuit in accordance with an embodiment of the present invention.

FIG. 2 is a circuit diagram exemplarily illustrating an equalizer shown in FIG. 1.

FIG. 3 is a circuit diagram exemplarily illustrating a driver shown in FIG. 1.

FIG. 4 is a circuit diagram exemplarily illustrating compensator shown in FIG. 1.

FIG. 5 is a circuit diagram exemplarily illustrating a driver and a compensator shown in FIG. 1.

FIG. 6 is a timing diagram illustrating input data and output data of an existing data driving circuit.

FIG. 7 is a timing diagram illustrating input data and output data of a data driving circuit shown in FIG. 1.

### DETAILED DESCRIPTION

Exemplary embodiments of the present invention are described below in more detail with reference to the accompanying drawings. These embodiments are provided so that this disclosure is thorough and complete, and fully conveys the scope of the present invention to those skilled in the art.

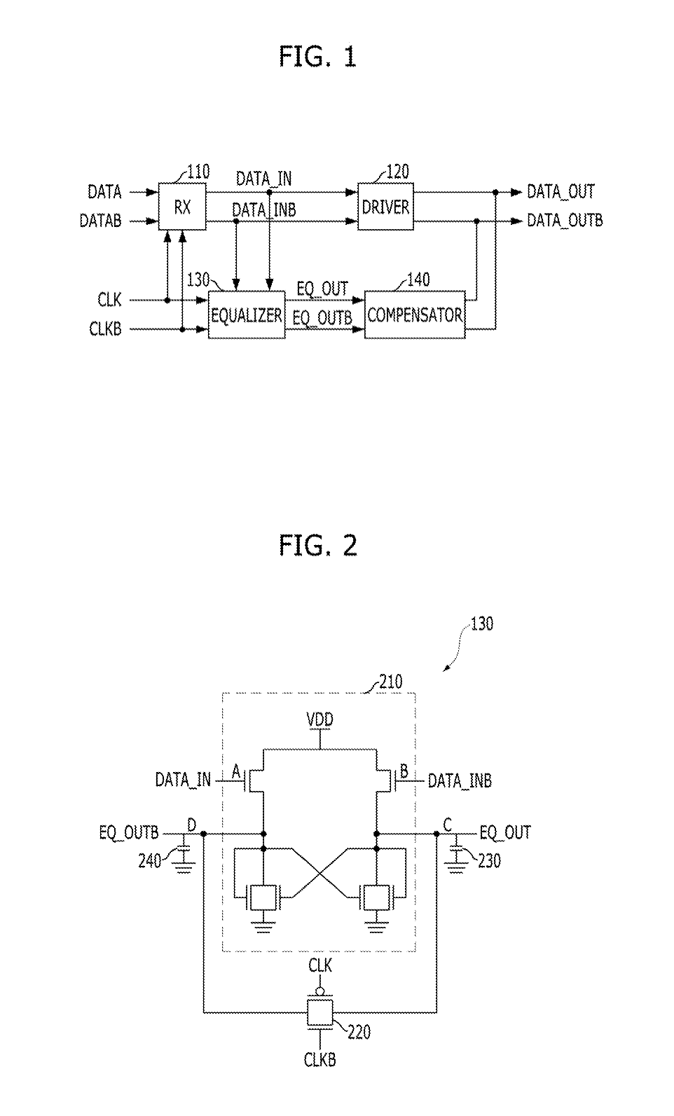

FIG. 1 is a block diagram illustrating a data driving circuit in accordance with an embodiment of the present invention.

Referring to FIG. 1, the data driving circuit may include a buffer 110, a driver 120, an equalizer 130 and a compensator 140. The data driving circuit may drive an input data to an output line. Generally, a data driving circuit may be used as a transmitter for transmitting a data and as a receiver for receiving a data transmitted from a transmitter. In other words, the data driving circuit may be a transmitter, a receiver, or both.

The buffer 110 may buffer data DATA and DATAB, which are transmitted from outside of the data driving circuit, and supply the buffered data as input data DATA_IN and DATA_INB. The buffer 110 may operate in synchronization with clocks CLK and CLKB. The driver 120 may drive output data DATA_OUT and DATA_OUTB in response to the input data DATA_IN and DATA_INB.

The equalizer 130 may amplify the input data DATA_IN and DATA_INB, and output the amplified input data as output signals EQ_OUT and EQ_OUTB while the clock CLK is at a first level, e.g., a logic low level. Also, the equalizer 130 may equalize the output signals EQ_OUT and EQ_OUTB while the clock CLK is at a second level, e.g., a logic high level.

The compensator 140 may drive the output data DATA_OUT and DATA_OUTB in response to the output signals EQ_OUT and EQ_OUTB of the equalizer 130. The compensator 140 may drive the output data DATA_OUT and DATA_OUTB by inverting the output signal EQ_OUT and the inverted output signal EQ_OUTB. In other words, the compensator 140 may drive the output data DATA_OUT and DATA_OUTB so that the output signal EQ_OUT may lower the absolute level of the inverted output data DATA_OUTB, and the inverted output signal EQ_OUTB may lower the absolute level of the output data DATA_OUT, thereby reducing the swing of the output data DATA_OUT and DATA_OUTB.

FIG. 2 is a circuit diagram exemplarily illustrating the equalizer 130 shown in FIG. 1.

Referring to FIG. 2, the equalizer 130 may include a differential amplifier 210, a switch 220, a first capacitor 230, and a second capacitor 240.

The differential amplifier 210 may output the output signal EQ_OUT at a first output terminal C thereof, and the inverted output signal EQ_OUTB at a second output terminal D thereof by differentially amplifying the input data DATA_IN inputted to a first input terminal A thereof, and the inverted input data DATA_MB inputted to a second input terminal B thereof. The differential amplifier 210 may drive the output data DATA_OUT to a logic high level and the inverted output signal EQ_OUTB to a logic low level when a voltage level of the input data DATA_IN is higher than a voltage level of the inverted input data DATA_MB. Also, the differential amplifier 210 may drive the output signal EQ_OUT to a logic low level and the inverted output signal EQ_OUTB to a logic high level when a voltage level of the inverted input data DATA_INB is higher than a voltage level of the input data DATA_IN.

The switch 220 may electrically couple the first output terminal C to the second output terminal D while the clock CLIA is at a second level, i.e., a logic high level, and the clock CLKB is at a first level i.e., a logic low level. As a result, the output signal EQ_OUT and the inverted output signal EQ_OUTB may be equalized while the clock CLK is at the second level. Meanwhile, the switch 220 may electrically decouple the first output terminal C from the second output terminal D while the clock CLK is at the first level. Therefore, an amplification result of the differential amplifier 210 may be outputted as the output signals EQ_OUT and EQ_OUTB while the clock is at the first level.

The first capacitor 230 may be electrically coupled with the first output terminal C, and the second capacitor 240 may be electrically coupled with the second output terminal D. The capacitors 230 and 240 may remove offsets and random jitter from the output signals EQ_OUT and EQ_OUTB.

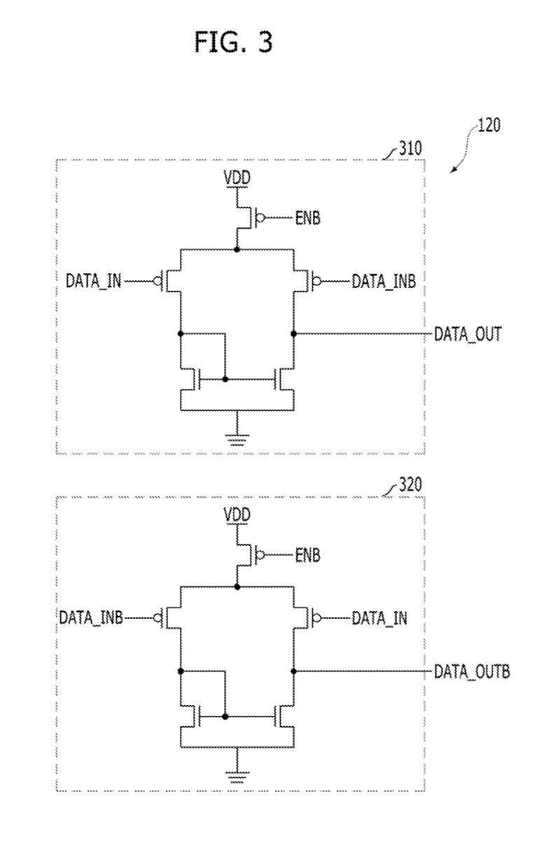

FIG. 3 is a circuit diagram exemplarily illustrating the driver 120 shown in FIG. 1.

Referring to FIG. 3, the driver 120 may include a first differential comparison unit 310 and a second differential comparison unit 320.

The first differential comparison unit 310 may compare the input data DATA_IN with the inverted input data DATA_INB. The first differential comparison unit 310 may drive the output data DATA_OUT to a logic high level when a voltage level of the input data DATA_IN is higher than a voltage level of the inverted input data DATA_INB, and may drive the output data DATA_OUT to a logic low level when a voltage level of the inverted input data DATA_MB is higher than a voltage level of the input data DATA_IN.

The second differential comparison unit 320 may compare the input data DATA_IN with the inverted input data DATA_INB. The second differential comparison unit 320 may drive the inverted output data DATA_OUTB to a logic low level when a voltage level of the input data DATA_IN is higher than a voltage level of the inverted input data DATA_INB, and may drive the inverted output data DATA_OUTB to a logic high level when a voltage level of the inverted input data DATA_INB is higher than a voltage level of the input data DATA_N.

An enabling signal ENB shown in FIG. 3 is a signal for enabling/disabling the driver 120. The driver 120 may be enabled and operate when the enabling signal ENB is at a logic low level.

FIG. 3 shows an example of a driver for driving the output data DATA_OUT and DATA_OUTB, a design modification of which may be obvious to those skilled in the art.

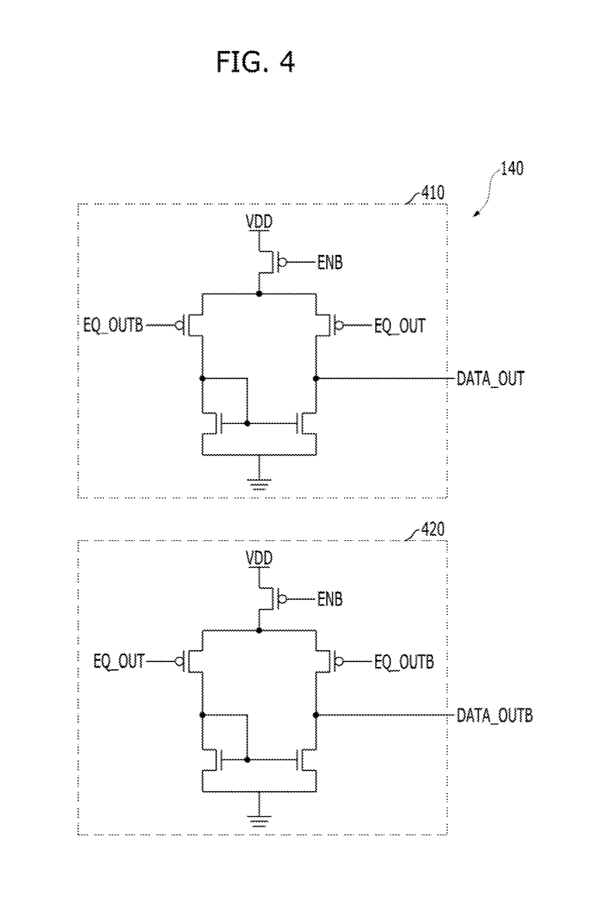

FIG. 4 is a circuit diagram exemplarily illustrating the compensator 140 shown in FIG. 1.

Referring to FIG. 4, the compensator 140 may include a third differential comparison unit 410 and a fourth differential comparison unit 420.

The third differential comparison unit 410 may compare the output signal EQ_OUT with the inverted output signal EQ_OUTB. The third differential comparison unit 410 may drive the output data DATA_OUT to a logic high level when a voltage level of the inverted output signal EQ_OUTB is higher than a voltage level of the output signal EQ_OUT, and may drive the output data DATA_OUT to a logic low level when a voltage level of the output signal EQ_OUT is higher than a voltage level of the inverted output signal EQ_OUTB.

The fourth differential comparison unit 420 may compare the output signal EQ_OUT with the inverted output signal EQ_OUTB. The fourth differential comparison unit 420 may drive the inverted output data DATA_OUTB to a logic low level when a voltage level of the inverted output signal EQ_OUTB is higher than a voltage level of the output signal EQ_OUT, and may drive the inverted output data DATA_OUTB to a logic high level when a voltage level of the output signal EQ_OUT is higher than a voltage level of the inverted output signal EQ_OUTB.

An enabling signal ENB shown in FIG. 4 is a signal for enabling/disabling the compensator 140. The compensator 140 may be enabled and operate when the enabling signal ENB is at a logic low level.

The differential comparison units 410 and 420 of the compensator 140 may be designed to have a weaker driving power than the differential comparison units 310 and 320 of the driver 120. For example, the amount of current flowing through the differential comparison units 410 and 420 may be smaller than the amount of a current flowing through the differential comparison units 310 and 320.

FIG. 4 shows an example of a compensator for driving the output data DATA_OUT and DATA_OUTB by inverting the output signals EQ_OUT and EQ_OUTB of the equalizer 130, and design modifications of the compensator may be obvious to those skilled in the art.

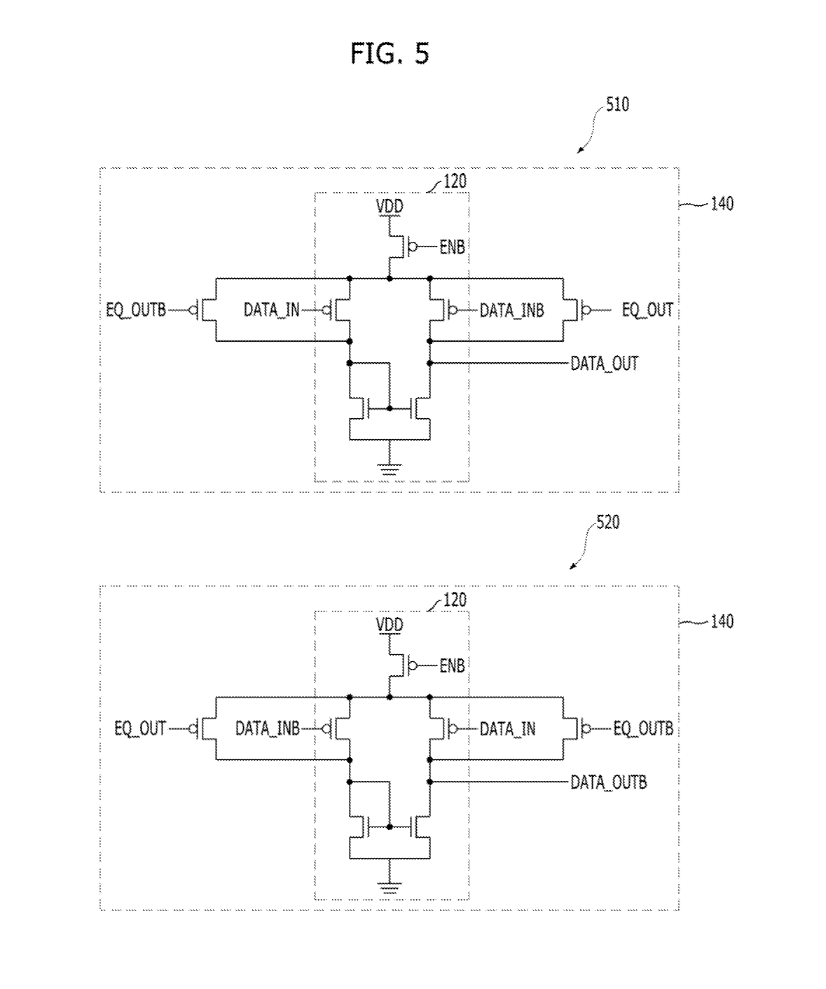

FIG. 5 is a circuit diagram exemplarily illustrating the driver 120 and the compensator 140 shown in FIG. 1. FIG. 5 shows a combination of the driver 120 and the compensator 140.

Referring to FIG. 5, the driver 120 and the compensator 140 to may include a fifth differential comparison unit 510 and a sixth differential comparison unit 520. As shown in FIG. 5, the driver 120 and the compensator 140 may share in parallel a structure of a differential comparison unit,

The fifth differential comparison unit 510 may compare the input data DATA_IN with the inverted input data DATA_INB as well as the second output signal EQ_OUTB with the output signal EQ_OUT. The fifth differential comparison unit 510 may drive the output data DATA_OUT to a logic high level as a voltage level of the input data DATA_IN is higher than a voltage level of the inverted input data DATA_INB, or as a voltage level of the second output signal EQ_OUTB is higher than a voltage level of the output signal EQ_OUT. Since the driver 120 and the compensator 140 may share in parallel a structure of a differential comparison unit, in the fifth differential comparison unit 510, a portion for comparing the input data DATA_IN with the inverted input data DATA_INB may correspond to the driver 120, and a portion for comparing the inverted output signal EQ_OUTB with the output signal EQ_OUT may correspond to the compensator 140. For the driving power of the compensator 140 to be less than the driving power of the driver 120, driving power of transistors that receive the inverted output signal EQ_OUTB and the output signal EQ_OUT may be designed to be less than the driving power of transistors that receive the input data DATA_IN and the inverted input data DATA_INB.

The sixth differential′ comparison unit 520 may compare the input data DATA_IN with the inverted input data DATA_INB as well as the second output signal EQ_OUTB with the output signal EQ_OUT. The sixth differential comparison unit 520 may drive the inverted output data DATA_OUTB to a logic low level as a voltage level of the input data DATA_IN is higher than a voltage level of the inverted input data DATA_INB, or as a voltage level of the second output signal EQ_OUTB is higher than a voltage level of the output signal EQ_OUT. Since the driver 120 and the compensator 140 may share in parallel a structure of a differential comparison unit, in the sixth differential comparison unit 520, a portion for comparing the input data DATA_IN with the inverted input data DATA_INB may correspond to the driver 120, and a portion for comparing the inverted output signal EQ_OUTB with the output signal EQ_OUT may correspond to the compensator 140. For the driving power of the compensator 140 less than the driving power of the driver 120, driving powers of transistors that receive the inverted output signal EQ_OUTB and the output signal EQ_OUT may be designed to be less than the driving power of transistors that receive the input data DATA_IN and the inverted input data DATA_INB.

When the driver 120 and the compensator 140 are combined with each other and form the data driving circuit as shown in FIG. 5, it is possible to prevent an increase in the area occupied by the circuit and to reduce current consumption.

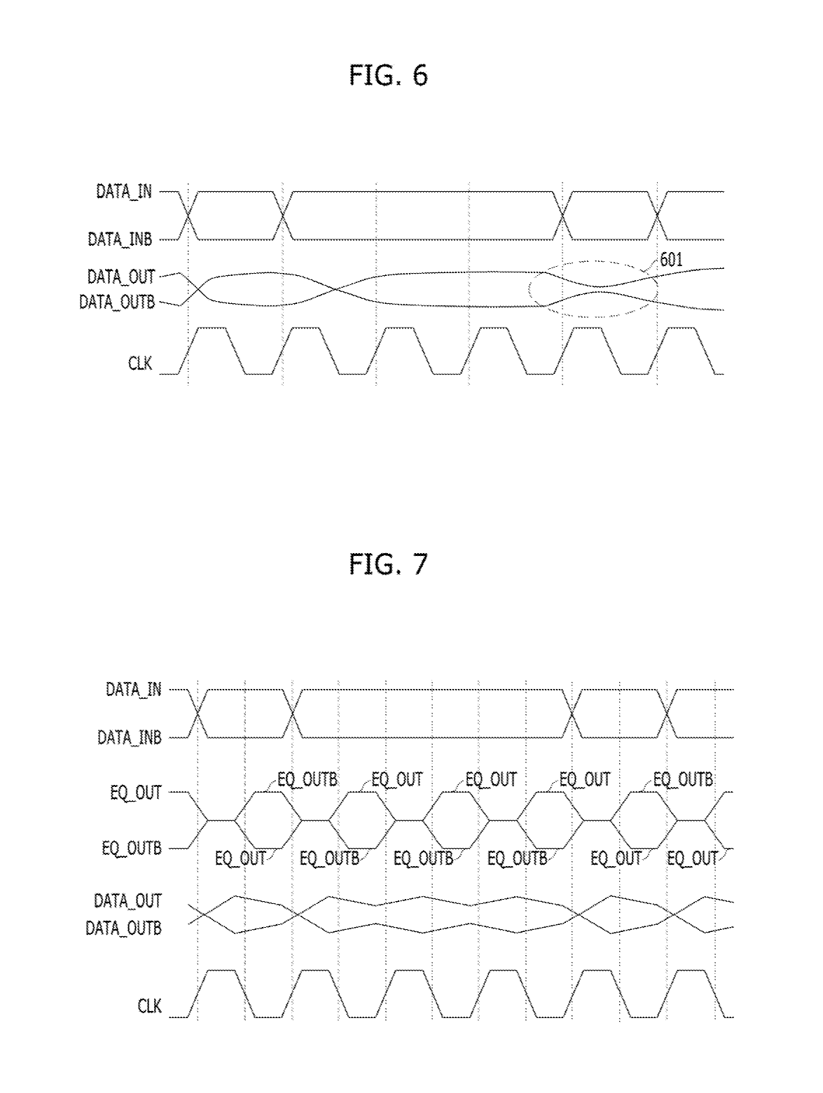

FIG. 6 is a timing diagram illustrating the input data DATA_IN and DATA_INB and the output data DATA_OUT and DATA_OUTB of an existing data driving circuit that does not have the equalizer 130 and the compensator 140. FIG. 7 is a timing diagram illustrating the input data DATA_IN and DATA_INB and the output data DATA_OUT and DATA_OUTB of the data driving circuit shown in FIG. 1.

Referring to FIG. 6, the output data DATA_OUT and DATA_OUTB does not have proper voltage levels in a section 601 where the input data DATA_IN and DATA_INB transitions after repeating of the same level.

However, referring to FIG. 7, the voltage levels of the output data DATA_OUT and DATA_OUTB do not increase or decrease excessively and the output data DATA_OUT and DATA_OUTB has proper voltage levels at all times since the swing of the output data DATA_OUT and DATA_OUTB is reduced by the equalizer 130 and the compensator 140 during the first level, e.g., the logic low level of the clock CLK. Also, it may be seen that the amount of a current consumption caused by the compensation operation by the equalizer 130 and the compensator 140 is not large since the compensation operation is not performed all the time but just during a half period of the clock CLK.

In accordance with the embodiments of the present invention, it is possible to design a data driving circuit that prevents failure of a data transmission due to data overdrive, offset and random jitter.

While the present invention has been described with respect to the specific embodiments, it is noted that the embodiments of the present invention are not restrictive but descriptive. Further, it is noted that the present invention may be achieved in various ways through substitution, change, and modification, by those skilled in the art without departing from the scope of the present invention as defined by the following claims.

What is claimed is:

1. A data driving circuit, comprising:
an equalizer suitable for transmitting an input data and an inverted input data as an output signal and an inverted output signal while a clock is at a first level, and equalizing the output signal while the clock is at a second level;
a driver suitable for driving an output data and an inverted output data in response to the input data and the inverted output signal; and
a compensator suitable for driving the output data and the inverted output data in response to the output signal and the inverted output signal.

2. The data driving circuit of claim 1, wherein the compensator drives the output data and the inverted output data by inverting the output signal and the inverted output signal.

3. The data driving circuit of claim 1, wherein a driving power of the compensator is less than a driving power of the driver.

4. The data driving circuit of claim 1, whereon the equalizer includes:
a differential amplifier suitable for outputting the output signal to a first output terminal and the inverted output signal to a second output terminal by differentially amplifying the input data inputted through a first input terminal and the inverted input data inputted through a second input terminal; and
a switch suitable for electrically coupling the first output terminal to the second output terminal while the clock is at a second level, and electrically decoupling the first output terminal from the second output terminal while the clock is at a first level.

5. The data driving circuit of claim 4, wherein the equalizer further includes:
a first capacitor coupled with the first output terminal; and
a second capacitor coupled with the second output terminal.

6. The data driving circuit of claim wherein the driver includes:
a first differential comparison unit suitable for driving the output data to a logic high level when a voltage level of the input data is higher than a voltage level of the inverted input data, and driving the output data to a logic low level when a voltage level of the inverted input data is higher than a voltage level of the input data; and
a second differential comparison unit suitable for driving the inverted output data to a logic low level when a voltage level of the input data is higher than a voltage level of the inverted input data, and driving the inverted output data to a logic high level when a voltage level of the inverted input data is higher than a voltage level of the input data.

7. The data driving circuit of claim wherein the compensator includes:
a third differential comparison unit suitable for driving the output data to a logic high level when a voltage level of the inverted output signal is higher than a voltage level of the output signal, and driving the output data to a logic low level when a voltage level of the output signal is higher than a voltage level of the inverted output signal; and
a fourth differential comparison unit suitable for driving the inverted output data to a logic low level when a voltage level of the inverted output signal is higher than a voltage level of the output signal, and driving the inverted output data to a logic high level when a voltage level of the output signal is higher than a voltage level of the inverted output signal.

8. The data driving circuit of claim 6,
wherein the first differential comparison unit further drives the output data to a logic high level when a voltage level of the inverted output signal is higher than a voltage level of the output signal, and drives the output data to a logic low level when a voltage level of the output signal is higher than a voltage level of the inverted output signal, and
wherein the second differential comparison unit further drives the inverted output data to a logic low level when a voltage level of the inverted output signal is higher than a voltage level of the output signal, and drives the inverted output data to a logic high level when a voltage level of the output signal is higher than a voltage level of the inverted output signal.

9. The data driving circuit of claim 1, further comprising:
a buffer for supplying the input data and the inverted input data by buffering an externally inputted data.

10. The data driving circuit of claim 9, wherein the buffer operates in synchronization with the clock.

11. The data driving circuit of claim 1, wherein the first level is at a logic low level, and the second level is at a logic high level.

12. A data driving circuit, comprising:
an amplifying unit suitable for outputting first and second amplified signals by differentially amplifying first and second input data for a predetermined duration in each period of a clock;
a driving unit suitable for outputting first and second output data by differentially amplifying the first and second input data; and
a compensation unit suitable for reducing a swing of the first and second output data using the first and second amplified signals.

13. The data driving circuit of claim 12, wherein the compensation unit drives the first and second output data so that the first amplified signal lowers an absolute level of the second output data, and the second amplified signal lowers an absolute level of the first output data.

14. The data driving circuit of claim 12, wherein a driving power of the compensation unit is less than a driving power of the driving unit.

15. The data driving circuit of claim 12, wherein the amplifying nit includes:
first and second capacitors coupled to nodes of the first and second amplified signals, respectively.

16. The data driving circuit of claim 12, wherein
the second input data is an n er ed version of the first input data,
the second amplified signal is an inverted version of the first amplified signal, and
the second output data is an inverted version of the first output data.
